(19) United States
(12) Patent Application Publication
(10) Pub. No.: US 2013/0221456 A1
(43) Pub. Date: Aug. 29, 2013

(54) Capacitance Type Micro-Silicon Microphone and Method for Making the Same

(71) Applicant: MEMSENSING MICROSYSTEMS TECHNOLOGY CO.,LTD., (US)

(72) Inventors: Gang Li, Suzhou City (CN); Wei Hu, Suzhou City (CN); Jia-Xin Mei, Suzhou City (CN)

(73) Assignee: MEMSENSING MICROSYSTEMS TECHNOLOGY CO., LTD., Suzhou City (CN)

(21) Appl. No.: 13/771,023

(22) Filed: Feb. 19, 2013

(30) Foreign Application Priority Data
Feb. 23, 2012 (CN) 201210041572.5

(51) Int. Cl. B81C 1/00; B81B 3/00

(52) U.S. Cl. CPC B81C 1/00158; B81B 3/0018
USPC 257/416; 438/53

(57) ABSTRACT

A capacitance type micro-silicon microphone includes a base, a backplate and a diaphragm positioned above the backplate in a suspended manner. The base includes a top face, a bottom face and a number of sound bores recessing inwardly from the top face. Bottom sides of the sound bores are in communication with each other so as to form an upper cavity. The base defines at least one lower cavity recessing inwardly from the bottom face. The backplate is positioned above the upper cavity in a suspended manner. The lower cavity is in communication with the upper cavity so as to jointly form a back cavity of the capacitance type micro-silicon microphone. Besides, a method for fabricating the capacitance type micro-silicon microphone is also disclosed.

### BACKGROUND OF THE INVENTION

1. Field of the Invention

The present invention relates to a field of Micro-Electro-Mechanical Systems (MEMS) based on silicon process, and more particularly to a capacitance type micro-silicon microphone and a method for making the same.

2. Description of Related Art

MEMS technology is a high technology rapidly developed in recent years. MEMS components can be manufactured by advanced semiconductor manufacturing processes to realize mass production. Compared with the traditional electronic components, the MEMS components are more competitive in profile, power consumption, weight and price etc. In current market, actual applications of the MEMS components include pressure sensors, acceleration sensors and silicon microphones etc.

The silicon microphones are usually assembled to a printed circuit board (PCB) through automatic surface mount technology (SMT). Since SMT process needs high temperatures, it is not suitable for assembling conventional electret condenser microphone (ECM) because stored charges of ECM are vulnerable to be easily leaked under high temperatures up to 260 degrees. Thus, conventional ECM needs to be assembled by hand. However, capacitance type micro-silicon microphones are capable of enduring high temperatures so that they are suitable for automatic SMT assembly. Besides, because of their potential advantages in miniaturization, performance, reliability, environmental endurance, low cost, and mass production capability, the capacitance type micro-silicon microphones manufactured by MEMS technologies are rapidly replacing the conventional ECM in consumer electronics, such as mobile phones, PDAs, MP3 and hearing aids etc.

Micro-silicon microphones have been in a research and development stage for more than 20 years and there are multiple detailed methods for realizing the micro-silicon microphones. The capacitance type micro-silicon microphones usually include a four-side fixed diagram, a backplate with a plurality of sound bores, and a small air gap between the diagram and the backplate. The conventional capacitance type micro-silicon microphone is formed by routine semiconductor process on a silicon base. The semiconductor process usually includes gradually depositing an insulation layer, a capacitance-type first plate (such as a backplate or a diagram), a sacrificial layer and a capacitance-type second plate (such as a backplate or a diagram). Materials of the capacitance-type first and the second plates can be achieved by multiple kinds of or multiple layers of materials (such as a composite film doped of polycrystalline silicon, metal and silicon nitride etc.). Materials of the sacrificial layer can be adopted with multiple materials (such as silicon dioxide or germanium etc.). However, the deposition process for fabricating the multi layers will result in complex manufacture and high cost.

Besides, another big problem in fabricating the micro-silicon microphone is how to control the stresses of the diagram and the backplate. Deposition is a conventional method for fabricating thin films. But, such thin films may have high residual stresses which usually include thermal mismatch stress and intrinsic stress. Residual stresses have great influence to the characteristics of the micro-silicon microphone, and the residual stresses may even invalid the micro-silicon microphone in serious conditions. Moreover, high residual stresses will greatly reduce the mechanical sensitivity of the micro-silicon microphone. The mechanical sensitivity is in direct proportion to the sensitivity of the micro-silicon microphone as a result that the high residual stresses will indirectly reduce the sensitivity of the micro-silicon microphone. Besides, the high residual stresses will curve the diagram and may cause the microphone characteristics unstable, so much as to be invalidated.

Hence, how to improve the sensitivity of the microphone has become the focus to those of ordinary skill in the art. In order to solve this problem, one method is to use additional process, such as anneal treatment, to reduce the residual stresses of the diagram. However, the effect of this method for reducing the residual stresses is not good. Beside, the repeatability of this method is not good and this method is difficult to realize. Another method is to make the remaining part of the diagram in free configurations, except one or more narrow beams for electrically connected out. Under this condition, the residual stresses of the diagram can be well released so as to achieve excellent sensitivity of the diagram. However, this method usually cause manufacture processes very complex.

Hence, it is desirable to provide an improved capacitance type micro-silicon microphone and an improved method for making the same.

### BRIEF SUMMARY OF THE INVENTION

The present invention provides a capacitance type micro-silicon microphone including a base, a backplate and a diaphragm positioned above the backplate in a suspended manner. The base includes a top face, a bottom face opposite to the top face and a plurality of sound bores recessing inwardly from the top face. Bottom sides of the sound bores are in communication with each other so as to form an upper cavity. The base defines at least one lower cavity recessing inwardly from the bottom face. The backplate is positioned above the upper cavity in a suspended manner as well. The lower cavity is in communication with the upper cavity so as to jointly form a back cavity of the capacitance type micro-silicon microphone.

Besides, a method for making a capacitance type micro-silicon microphone is disclosed including the following steps:

S1: providing a silicon base, adopting micro-processing technology on a top face of the silicon base to form a reticulate and suspended structure as a backplate and let generating suspend vacancy acting as an upper cavity;
S2: depositing silicon dioxide on the backplate and on an inner surface of the upper cavity so as to form an insulation layer, the insulation layer formed in the upper cavity acting as a self-stop layer when etching to form a lower cavity;
S3: depositing a polysilicon layer on the insulation layer and then using lithography etching technology to etch the polysilicon layer so as to form a diagram of the capacitance type micro-silicon microphone;
S4: depositing metal on the diagram and the silicon base so as to form pressure solder joints;
S5: fabricating the lower cavity from a bottom face of the silicon base through lithography etching technology and deep silicon etching technology, the lithography etching technology and deep silicon etching technology stopping at the self-stop layer; and
S6: eroding the self-stop layer from the bottom face of the silicon base and further eroding the insulation layer between the backplate and the diagram so as to communicate the upper cavity and the lower cavity to form a back cavity of the capacitance type micro-silicon microphone, and release the diagram to be a movable structure.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 to 14 are flow diagrams for making a capacitance type micro-silicon microphone in accordance with a first embodiment of the present invention;

FIG. 15 is a bottom view of the capacitance type micro-silicon microphone as shown in FIG. 14;

FIG. 16 is schematic cross-sectional view of a capacitance type micro-silicon microphone in accordance with a second embodiment of the present invention;

FIG. 17 is a bottom view of the capacitance type micro-silicon microphone as shown in FIG. 16; and

FIGS. 18 to 22 are part flow diagrams for making the capacitance type micro-silicon microphone in accordance with an alternative embodiment of the present invention.

### DETAILED DESCRIPTION OF THE PREFERRED EMBODIMENTS

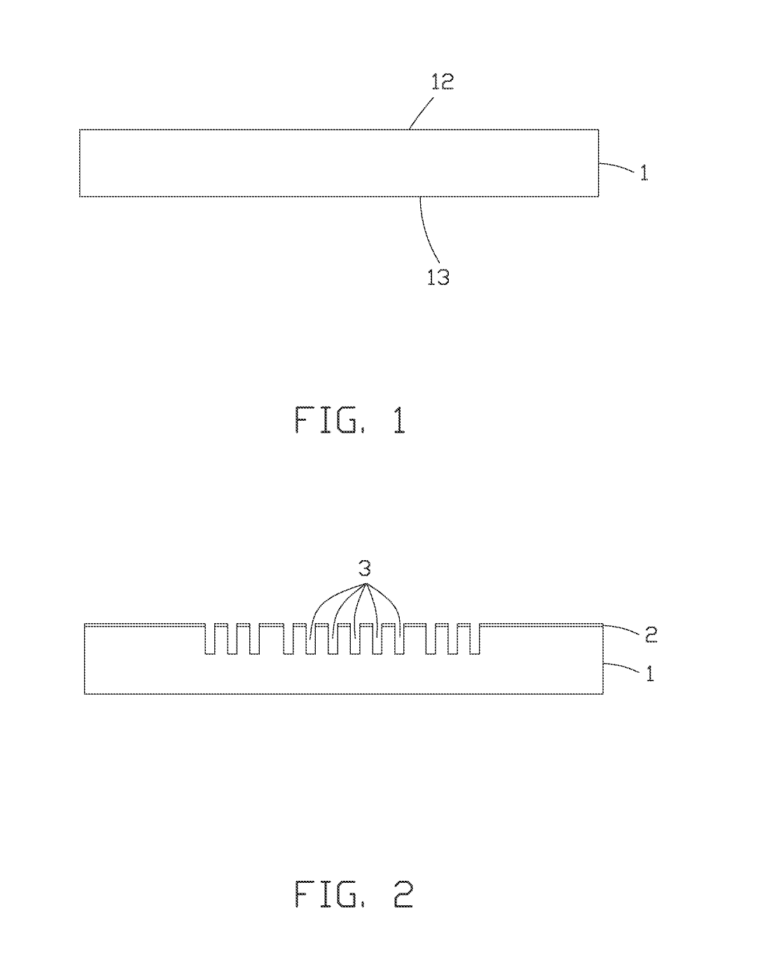

Reference will now be made to the drawing figures to describe the preferred embodiment of the present invention in detail. Referring to FIGS. 1-15, according to a first embodiment of the present invention, a method for making a capacitance type micro-silicon microphone is disclosed with the following steps:

Step S1: referring to FIGS. 1 and 2, providing a silicon base 1 and then adopting deposition technology to fabricate a silicon dioxide film 2 on a top face 12 of the silicon base 1. The silicon base 1 is made of single crystal silicon. The silicon dioxide film 2 acts as a mask layer in subsequent deep silicon etching technology.

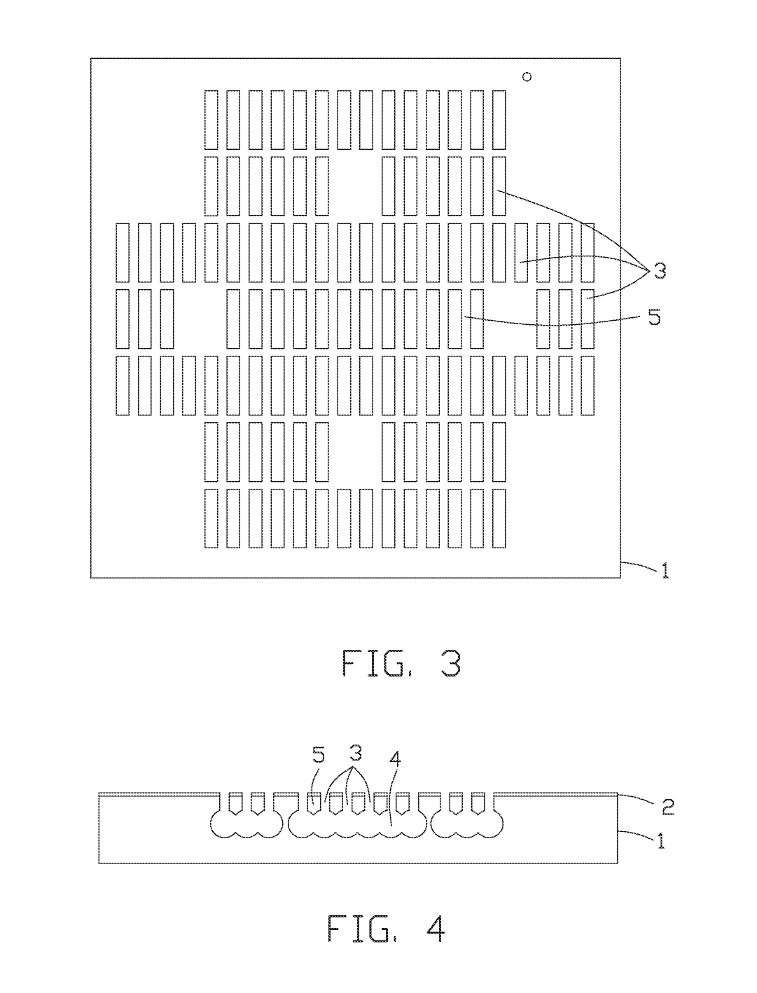

Step S2: referring to FIGS. 2 and 3, forming a plurality of trenches 3 in the silicon base 1 through lithography etching technology, through eroding the mask layer, and through anisotropic deep silicon etching technology. The distribution of the trenches 3 determines the figure and the size of a backplate. According to the illustrated embodiment of the present invention, a cross-sectional figure of each trench 3 is rectangular. It is understood that the cross-sectional figure of each trench 3 may be other shapes, such as round. The distribution, the figure and the size of the trenches 3 may be designed according to different requirement of sound characteristics.

Step 3: referring to FIG. 4, forming an upper cavity 4 below the trenches 3 through isotropic deep silicon etching technology. The size of the upper cavity 4 is determined by the distribution of the trenches 3. Simultaneously, a backplate 5 is formed on the silicon base 1 and the backplate 5 is a part of the silicon base 1. The backplate 5 is also made of single crystal silicon with reticulate and suspended structure. Under this condition, the backplate 5 with the foregoing structure is better than that fabricated by Low Pressure Chemical Vapor Deposition (LPCVD) technology in mechanical characteristics and thickness. The trenches 3 become sound bores after foregoing treatment. The sound bores are adapted for sound transmission and damping adjustment. The depth of the trenches 3 can be adjusted by changing parameters of isotropic silicon etching process and anisotropic silicon etching process, and can be designed according to different requirement of sound characteristics. The design flexibility of fabricating the backplate 5 and the sound bores according to foregoing method is much better than LPCVD.

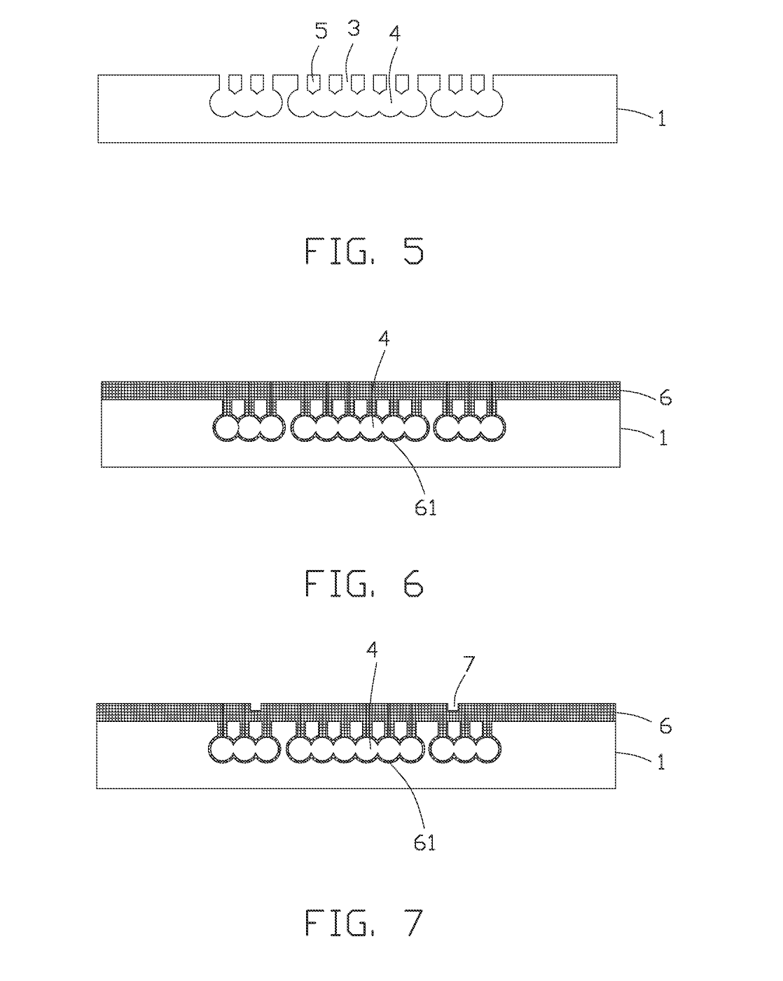

Step S4: referring to FIGS. 5 and 6, removing the silicon dioxide film 2 and then depositing silicon dioxide on a top surface of the backplate 5 and on an inner surface of the upper cavity 4 so as to form an insulation layer 6. The insulation layer 6 which is formed in the upper cavity 4 acts as a self-stop layer when etching to form a lower cavity.

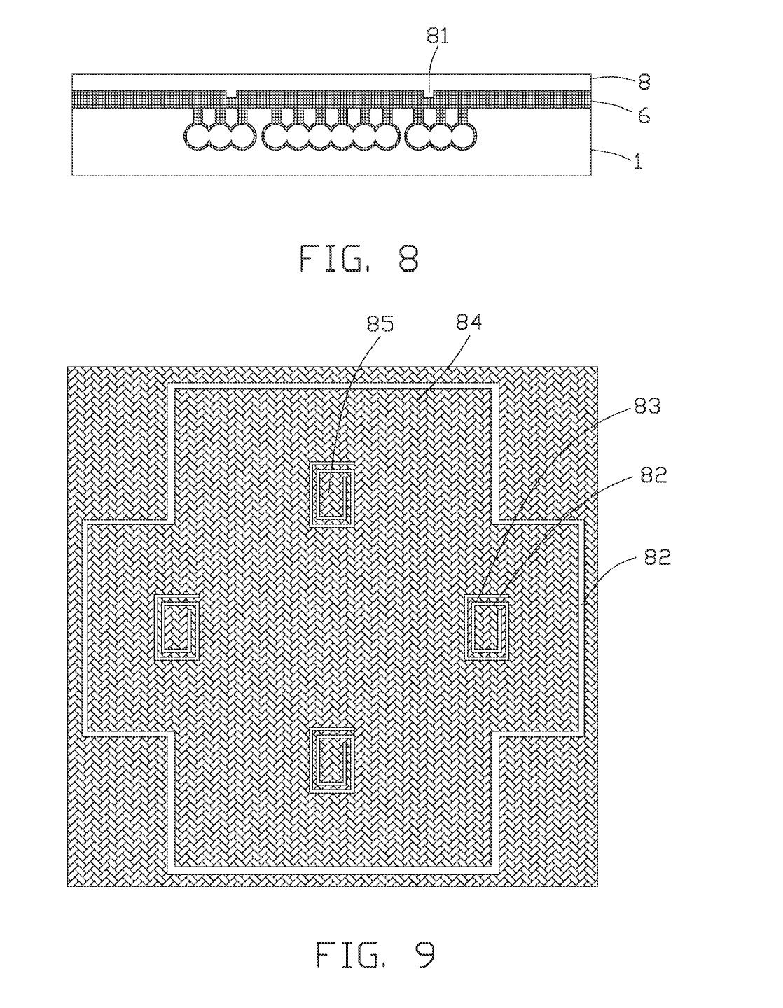

Step S5: referring to FIGS. 7 and 8, forming a recess 7 on top of the insulation layer 6 through lithography etching technology and corrosion technology, and then depositing a polysilicon layer 8 on the insulation layer 6 through LPCVD technology. The polysilicon layer 8 fills in the recess 7 to form a protrusion 81 which is adapted for preventing a diagram 84 from adhibiting the backplate 5.

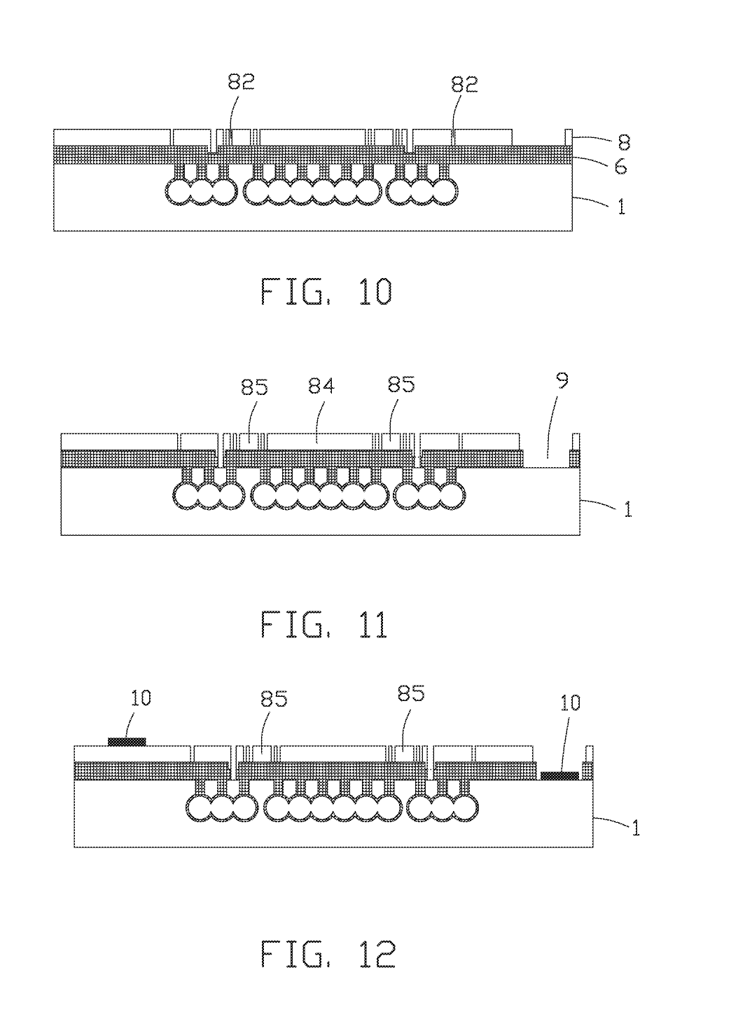

Step S6: referring to FIGS. 9 and 10, fabricating a plurality of narrow grooves 82 in the polysilicon layer 8 through lithography etching technology so as to form the diagram 84, spiral beams 83 and supporting portions 85. The diagram 84 is connected to the supporting portions 85 through spiral beams 83. The spiral beams 83 are adapted for robust stress release so that the sound characteristics of can be less influenced by the polysilicon layer 8 which is made through LPCVD technology. It is understandable that the spiral beams 83 can also be replaced by other flexible beams, such as bow beams etc.

Step S7: referring to FIG. 11, etching and eroding part of the insulation layer 6 to form an opening 9. After such process, part of the silicon base 1 is exposed to the opening 9 for fabricating a pressure solder joint 10.

Step S8: referring to FIG. 12, fabricating a pair of pressure solder joints 10 by metal depositing/sputtering, lithography etching and corrosion technologies. One of the pressure solder joint 10 is formed on the polysilicon layer 8 and the other of the pressure solder joint 10 is formed on the silicon base 1.

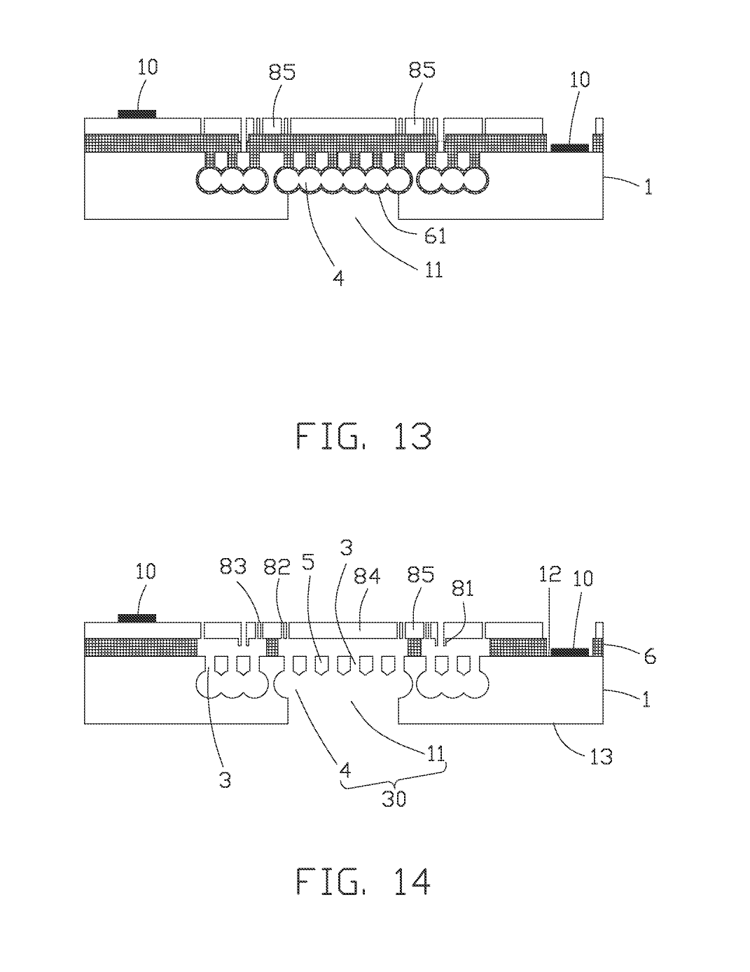

Step S9: referring to FIG. 13, fabricating a lower cavity 11 from a bottom face 13 of the silicon base 1 through dual-face lithography etching technology and deep silicon etching technology. The lithography etching technology and deep silicon etching technology stop at the self-stop layer 61.

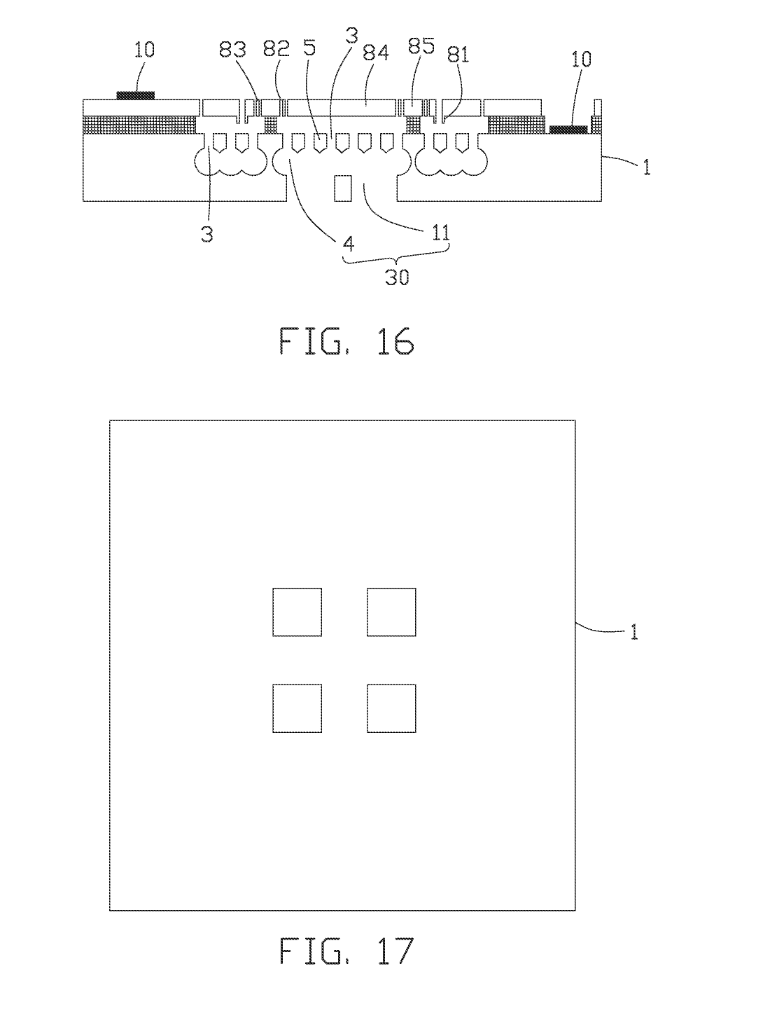

Step S10: referring to FIG. 14, removing the self-stop layer 61 from the bottom face 13 of the silicon base 1 through wet eroding technology so as to communicate the upper cavity 4 and the lower cavity 11 to jointly form a back cavity 30 of the capacitance type micro-silicon microphone. The lower cavity 11 is in an integrally emptied configuration. However, the lower cavity 11 can be set another integral figure or a combination of multiple figures. As shown in FIGS. 16 and 17, the lower cavity 11 is comprised of four small rectangular cavities 111. The small rectangular cavities 111 are in communication with the upper cavity 4 so as to jointly from the back cavity 30. It is understandable that, when the lower cavity 11 is comprised of the four small rectangular cavities 111, a cross-sectional figure of the back cavity 30 is T-shaped. However, the cross-sectional figure of the back cavity 30 can be set in other shapes according to other figures of the lower cavity 11. Besides, the insulation layer 6 between the backplate 5 and the diagram 84 is also eroded so as to release the diagram 84 to be a movable structure. However, some insulation layer 6 is remained, such as the insulation layer 6 between the supporting portions 85 and the silicon base 1.

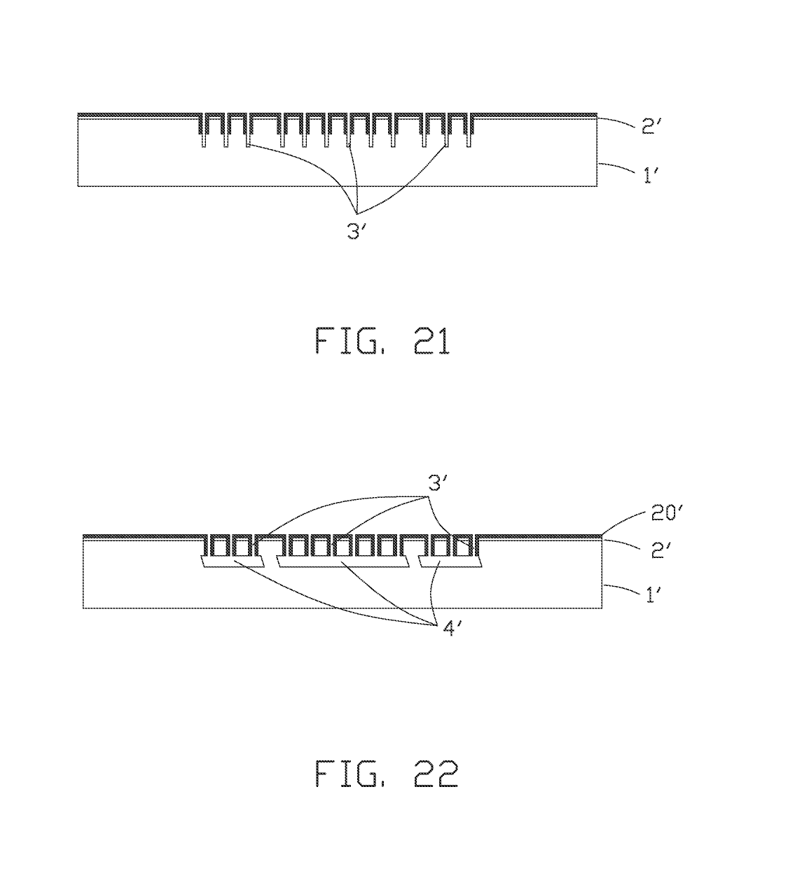

Referring to FIGS. 18 and 22, according to an alternative embodiment of the present invention, another method for making the capacitance type micro-silicon microphone is disclosed. The another method is similar to the method described above and the differences therebetween are the steps for fabricating the backplate 5, 5′. In the alternative embodiment, the silicon base 1 is made of crystal orientation <111> silicon. The method of making the backplate 5′ includes the following steps:

Step 1′: referring to FIGS. 18 and 19, adopting deposition technology to fabricate a silicon dioxide film 2′ on the top face of the silicon base 1′, and then using lithography etching technology and anisotropic silicon etching technology to form a plurality of trenches 3′. The silicon dioxide film 2′ acts as a mask layer.

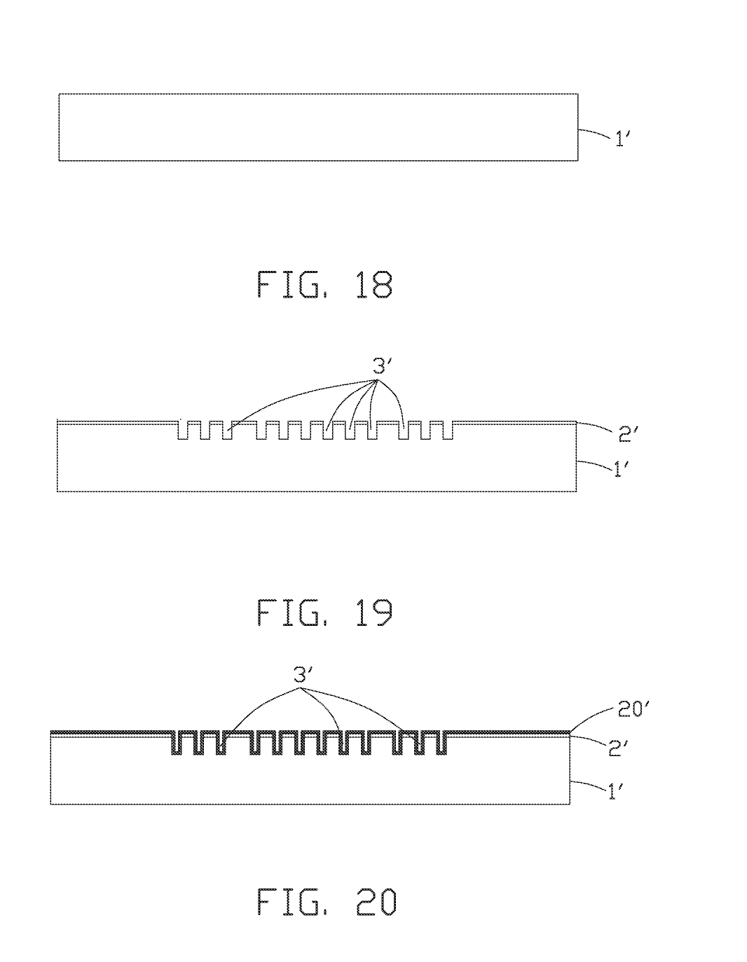

Step 2′: referring to FIG. 20, adopting LPCVD technology to fabricate another silicon dioxide 20′ on inner sides and bottom sides of the trenches 3′.

Step 3′: referring to FIG. 21, adopting anisotropic etching technology to remove the another silicon dioxide 20′ formed on the bottom sides of the trenches 3′, and then adopting anisotropic etching technology to deepen the trenches 3′. Because side walls of the trenches 3′ have already been covered with the another silicon dioxide 20′, the width of each trench 3′ can not be enlarged.

Step 4′: referring to FIG. 22, adopting KOH or tetramethylammonium hydroxide (TMAH) into the trenches 3′ so as to etch the silicon base 1′ and then form an upper cavity 4′. Because of the anisotropic etching technology and the crystal orientation <111> silicon, a figuration of the upper cavity 4′ as shown in FIG. 22 is ultimately formed.

Since other steps for making the capacitance type micro-silicon microphone are the same as these described in the first embodiment, repeated description is omitted herein.

Besides, not all the steps described above are indispensable, under this condition, the steps need to be renumbered as shown in the claims.

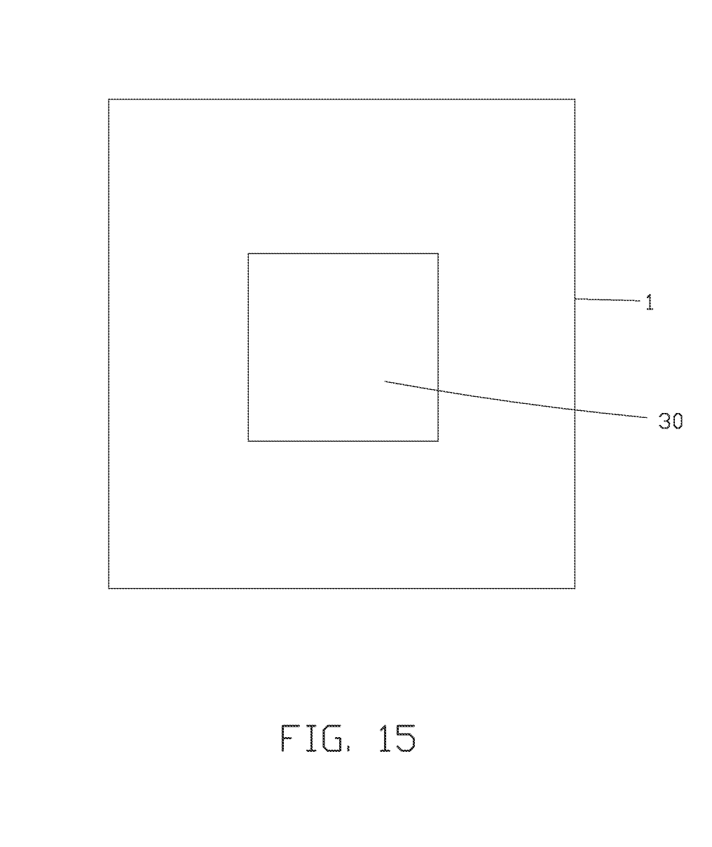

Referring to FIGS. 14 and 15, according to the illustrated embodiments of the present invention, the capacitance type micro-silicon microphone made from the forgoing methods includes a silicon base 1, a diagram 84, a pair of pressure solder joints 10. The silicon base 1 includes a top face 12, a bottom face 13 opposite to the top face 12, a plurality of sound bores 3 recessing inwardly from the top face 12, an upper cavity 4 formed by communicating bottom sides of the sound bores 3, a backplate 5 positioned above the upper cavity 4 in a suspended manner, and at least one lower cavity 11 recessing inwardly from the bottom face 13. A cross-sectional figure of each sound bore 3 is round or rectangular or other shapes. The lower cavity 11 is in communication with the upper cavity 4 so as to jointly form a back cavity 30 of the capacitance type micro-silicon microphone.

Referring to FIGS. 1 to 14, since the silicon base 1 is partly emptied from the top face 12 so as to form the backplate 5, the upper cavity 4 is formed simultaneously with the backplate 5, the lower cavity 11 is etched from the bottom face 13 of the silicon base 1, and the back cavity 30 is ultimately formed by connecting the upper cavity 4 and the lower cavity 11, the figure and the size of the backplate 5 can independently designed according to acoustic requirement in spite of considering the figure and the size of the back cavity 30. According to the illustrated embodiments of the present invention, the lower cavity 11 comprises an integral figure (as shown FIG. 15) or comprises a combination of multiple figures (as shown in FIGS. 16 and 17). In detail, the lower cavity 11 is comprised of four small rectangular cavities 111. The small rectangular cavities 111 are in communication with the upper cavity 4 so as to jointly from the back cavity 30. It is understandable that, when the lower cavity 11 is comprised of the four small rectangular cavities 111, a cross-sectional figure of the back cavity 30 is T-shaped. However, the cross-sectional figure of the back cavity 30 can be set in other shapes according to other figures of the lower cavity 11.

The diagram 84 is positioned above the backplate 5 in a suspended manner as well. The diagram 84 includes a plurality of supporting portions 85 connected to the silicon base 1. The supporting portions 85 are located at middle sections of the diagram 84. An insulation layer 6 is formed between the supporting portions 85 and the silicon base 1. It is known that the stress of the diagram 84 will influence the sensitivity of the capacitance type micro-silicon microphone, and it is difficult to control the homogeneity and the consistency of the stress during mass production. However, with flexible beams, such as spiral beams 83, connecting the supporting portions 85 and the diagram 84, the above shortcomings can be well overcame, because the flexible beams can completely release the residual stress of the diagram 84. It is understandable that the flexible beams can also be those bow beams etc. As shown in FIG. 9, the supporting portions 85 and the spiral beams 83 are formed by fabricating a plurality of narrow grooves 82 in the diagram 84. Besides, a plurality of protrusions 81 are formed on the diagram 84 and extends towards the backplate 5 for preventing the diagram 84 from adhibiting the backplate 5. The protrusions 81 are positioned above the backplate 5 in a suspended manner. At least one of the protrusions 81 defines a groove (not labeled) extending therethrough.

It is to be understood, however, that even though numerous, characteristics and advantages of the present invention have been set forth in the foregoing description, together with details of the structure and function of the invention, the disclosed is illustrative only, and changes may be made in detail, especially in matters of number, shape, size, and arrangement of parts within the principles of the invention to the full extent indicated by the broadest general meaning of the terms in which the appended claims are expressed.

What is claimed is:

1. A capacitance type micro-silicon microphone comprising:
a base having a top face, a bottom face opposite to the top face and a plurality of sound bores recessing inwardly from the top face, bottom sides of the sound bores being in communication with each other so as to form an upper cavity, the base defining at least one lower cavity recessing inwardly from the bottom face;
a backplate positioned above the upper cavity in a suspended manner; and
a diaphragm positioned above the backplate in a suspended manner as well; wherein
the lower cavity is in communication with the upper cavity so as to jointly form a back cavity of the capacitance type micro-silicon microphone.

2. The capacitance type micro-silicon microphone as claimed in claim 1, wherein the lower cavity comprises an integral figure or a combination of multiple figures.

3. The capacitance type micro-silicon microphone as claimed in claim 1, wherein a cross-sectional figure of the back cavity is T-shaped.

4. The capacitance type micro-silicon microphone as claimed in claim 1, wherein the lower cavity is comprised of four small rectangular cavities.

5. The capacitance type micro-silicon microphone as claimed in claim 1, wherein a cross-sectional figure of each sound bore is round or rectangular.

6. The capacitance type micro-silicon microphone as claimed in claim 1, wherein the diagram comprises a plurality of supporting portions connected to the base, and the supporting portions are connected to the diaphragm through flexible beams.

7. The capacitance type micro-silicon microphone as claimed in claim 6, wherein the flexible beams comprise spiral beams.

8. The capacitance type micro-silicon microphone as claimed in claim 7, wherein each of the supporting portions and the spiral beams is formed by fabricating a plurality of narrow grooves in the diagram.

9. The capacitance type micro-silicon microphone as claimed in claim 1, further comprising a plurality of protrusions extending from the diagram and towards the backplate, and the protrusions are positioned above the backplate in a suspended manner.

10. The capacitance type micro-silicon microphone as claimed in claim 9, wherein at least one of the protrusions defines a groove extending therethrough.

11. The capacitance type micro-silicon microphone as claimed in claim 1, further comprising a first pressure solder joint formed on the base and a second pressure solder joint positioned above the first pressure solder joint.

12. A method for making a capacitance type micro-silicon microphone comprising the following steps:
S1: providing a silicon base, adopting micro-processing technology on a top face of the silicon base to form a reticulate and suspended structure as a backplate and let generating suspend vacancy acting as an upper cavity;
S2: depositing silicon dioxide on the backplate and on an inner surface of the upper cavity so as to form an insulation layer, the insulation layer formed in the upper cavity acting as a self-stop layer when etching to form a lower cavity;
S3: depositing a polysilicon layer on the insulation layer and then using lithography etching technology to etch the polysilicon layer so as to form a diagram of the capacitance type micro-silicon microphone;
S4: depositing metal on the diagram and the silicon base so as to form pressure solder joints;
S5: fabricating the lower cavity from a bottom face of the silicon base through lithography etching technology and deep silicon etching technology, the lithography etching technology and deep silicon etching technology stopping at the self-stop layer; and
S6: eroding the self-stop layer from the bottom face of the silicon base and further eroding the insulation layer between the backplate and the diagram so as to communicate the upper cavity and the lower cavity to form a back cavity of the capacitance type micro-silicon microphone, and release the diagram to be a movable structure.

13. The method as claimed in claim 12, wherein the backplate and the upper cavity in the step S1 are formed by the following steps:
S11: adopting deposition technology to fabricate a silicon dioxide film on the top face of the silicon base, the silicon dioxide film acting as a mask layer in the subsequent deep silicon etching technology;
S12: forming a plurality of trenches in the silicon base through lithography etching technology, through eroding the mask layer, and through anisotropic deep silicon etching technology; and
S13: forming the upper cavity below the trenches through isotropic deep silicon etching technology.

14. The method as claimed in claim 13, wherein in the step S11, a cross-sectional figure of each trench is round or rectangular.

15. The method as claimed in claim 12, wherein the backplate and the upper cavity in the step S1 are formed by the following steps:
S11′: adopting deposition technology to fabricate a silicon dioxide film on the top face of the silicon base, the silicon dioxide film acting as a mask layer, then using lithography etching technology and anisotropic silicon etching technology to form a plurality of trenches;
S12′: adopting Low Pressure Chemical Vapor Deposition (LPCVD) technology to fabricate another silicon dioxide on inner sides and bottom sides of the trenches; and
S13′: adopting anisotropic etching technology to remove the another silicon dioxide formed on the bottom sides of the trenches, and then adopting anisotropic etching technology to deepen the trenches.

16. The method as claimed in claim 12, further comprising a step between the step S2 and the step S3:
forming a recess on top of the insulation layer through lithography etching technology and corrosion technology, and then in step S3, during depositing the polysilicon layer, the polysilicon layer filling in the recess to form a protrusion.

17. The method as claimed in claim 12, wherein in the step S3, when forming the diagram, supporting portions and spiral beams for connecting the diagram and the supporting portions are simultaneously formed through the lithography etching technology.

18. The method as claimed in claim 17, wherein the spiral beams are formed by fabricating a plurality of narrow grooves in the diagram.

19. The method as claimed in claim 12, wherein the lower cavity comprises an integral figure or a combination of multiple figures.

20. The method as claimed in claim 12, wherein a cross-sectional figure of the back cavity is T-shaped.
